(19) United States
(12) Patent Application Publication
(10) Pub. No.: US 2026/0190383 A1
(43) Pub. Date: Jul. 2, 2026

(54) HIGH VOLTAGE SEMICONDUCTOR DEVICES

(71) Applicant: Samsung Electronics Co., Ltd., Suwon-si (KR)

(72) Inventors: Hiroki FUJII, Suwon-si (KR); Jaehyun YOO, Suwon-si (KR); Dawon JEONG, Suwon-si (KR); Kunsik SUNG, Suwon-si (KR)

(73) Assignee: Samsung Electronics Co., Ltd., Suwon-si (KR)

(21) Appl. No.: 19/425,172

(22) Filed: Dec. 18, 2025

(30) Foreign Application Priority Data
Dec. 26, 2024 (KR) 10-2024-0197454

(51) Int. Cl. H10D 30/65; H10D 30/01; H10D 62/60; H10D 64/27

(52) U.S. Cl. CPC H10D 30/658; H10D 62/60; H10D 64/513; H10D 64/514; H10D 64/518; H10D 30/0289

(57) ABSTRACT

A high voltage semiconductor device includes a substrate, a well region of a first conductivity-type in the substrate, a first drift region and a second drift region each of a second conductivity-type in the well region, and a gate trench between the first drift region and the second drift region. The gate trench has a bottom defined by the well region, and two sidewalls defined by the first drift region and the second drift region, respectively. Each of the two sidewalls has a step. The high voltage semiconductor device further includes a gate insulating film covering the bottom and the two sidewalls of the gate trench, and a gate electrode in the gate trench.

### CROSS-REFERENCE TO RELATED APPLICATION(S)

This U.S. non-provisional application claims priority under 35 U.S.C. 119 to Korean Patent Application No. 10-2024-0197454 filed on Dec. 26, 2024, in the Korean Intellectual Property Office, the disclosure of which is incorporated herein by reference in its entirety.

### BACKGROUND

Example embodiments relate to high voltage semiconductor devices.

High-voltage semiconductor devices are used in various integrated circuits such as nonvolatile memory or display driver ICs (DDIs). For example, high-voltage semiconductor devices include high-voltage transistors having recessed trench channels, and may be used together with transistors (for example, transistors having flat channels) that have different operating voltages or functions.

It is advantageous for high-voltage semiconductor devices such as high-voltage transistors to have improved electrical characteristics such as high breakdown voltage of the impurity region forming the source/drain of high-voltage transistors having recessed channels.

### SUMMARY

Example embodiments are directed to a high voltage semiconductor device having improved electrical characteristics.

According to some example embodiments, a high voltage semiconductor device includes a substrate, a well region of a first conductivity-type in the substrate, a first drift region and a second drift region each of a second conductivity-type in the well region, and a gate trench between the first drift region and the second drift region. The gate trench has a bottom defined by the well region, and two sidewalls defined by the first drift region and the second drift region, respectively. Each of the two sidewalls has a step. The high voltage semiconductor device further includes a gate insulating film covering the bottom and the two sidewalls of the gate trench, and a gate electrode in the gate trench.

According to some example embodiments, a high voltage semiconductor device includes a substrate, well region of a first conductivity-type in the substrate, a first drift region and a second drift region of a second conductivity-type in the well region, and a gate trench between the first drift region and the second drift region. The gate trench has a bottom defined by the well region and two inclined sidewalls respectively defined by the first drift region and the second drift region. The bottom of the gate trench has a corner structure formed of two steps. The high voltage semiconductor device further includes a gate insulating film covering the bottom and the two inclined sidewalls of the gate trench, a gate electrode in the gate trench, an interlayer insulating layer on the substrate and covering the first and second drift regions and the gate electrode, and a first contact plug and a second contact plug penetrating the interlayer insulating layer and respectively connected to the first drift region and the second drift region.

According to some example embodiments, a high voltage semiconductor device includes a substrate, a well region of a first conductivity-type in the substrate, a first drift region and a second drift region of a second conductivity-type in the well region, and a gate trench between the first drift region and a second drift region and having a bottom defined at least partially by the well region and two sidewalls respectively defined by the first drift region and the second drift region. Each sidewall of the two sidewalls has a step, and an upper sidewall and a lower sidewall separated by the step. The high voltage semiconductor device further includes a gate insulating film covering the bottom and the two sidewalls of the gate trench, a gate electrode in the gate trench and on the first drift region and the second drift region adjacent to the gate trench, an interlayer insulating layer on the substrate and covering the first drift region and the second drift region and the gate electrode, and a first contact plug and a second contact plug penetrating the interlayer insulating layer and connected to the first drift region and the second drift region, respectively.

According to some example embodiments, a method of manufacturing a high voltage semiconductor device includes forming a well region of a first conductivity-type in substrate, forming a first drift region and a second drift region each of a second conductivity-type in the well region, and forming a gate trench between the first drift region and the second drift region. The gate trench has a bottom defined by the well region, and two sidewalls defined by the first drift region and the second drift region, respectively. Each of the two sidewalls has a step. The method further includes forming a gate insulating film on the bottom and the two sidewalls of the gate trench, and forming a gate electrode in the gate trench. According to some example embodiments, the step defines an upper sidewall and a lower sidewall of each of the two sidewalls of the gate trench, and a height of the upper sidewall is greater than a height of the lower sidewall. According to some example embodiments, the upper sidewall and the lower sidewall are inclined. According to some example embodiments, the gate trench has a lower corner connecting the lower sidewall and the bottom, and an upper corner located at a lower end of the upper sidewall, and the lower corner is rounded. According to some example embodiments, the first drift region and the second drift region respectively cover at least a portion of the lower corner of the gate trench. According to some example embodiments, wherein the upper corner is rounded.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a high voltage semiconductor device according to some example embodiments.

FIG. 2 is a cross-sectional side view taken along line I-I′ of the high voltage semiconductor device illustrated in FIG. 1.

FIG. 3 is a partial enlarged view illustrating a portion A1 of the high voltage semiconductor device illustrated in FIG. 2.

FIGS. 4A and 4B and FIGS. 5A and 5B illustrate impact ionization in high voltage semiconductor devices (comparative examples and example embodiments) for different gate structures.

FIGS. 6A and 6B illustrate I-V curves of high voltage semiconductor devices according to comparative examples and example embodiments, respectively.

FIGS. 7A, 7B, 7C, 7D, 7E, and 7F are cross-sectional views of some processes of a method of manufacturing a high voltage semiconductor device, according to some example embodiments.

FIGS. 8A, 8B, 8C, 8D, and 8E are cross-sectional views of some processes of a method of manufacturing a high voltage semiconductor device according to some example embodiments.

FIG. 9 is a cross-sectional view illustrating a high voltage semiconductor device according to some example embodiments.

FIGS. 10A and 10B illustrate impact ionization degrees in high voltage semiconductor devices for different gate structures (Examples 1 and 2).

FIG. 11 illustrates I-V curves of high voltage semiconductor devices according to Examples 1 and 2.

### DETAILED DESCRIPTION

Hereinafter, example embodiments will be described with reference to the accompanying drawings.

In the drawings, the thickness of layers, films, panels, regions, etc., are exaggerated for clarity.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

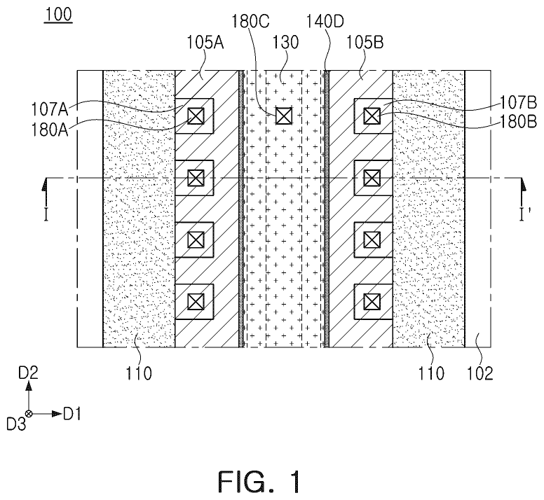

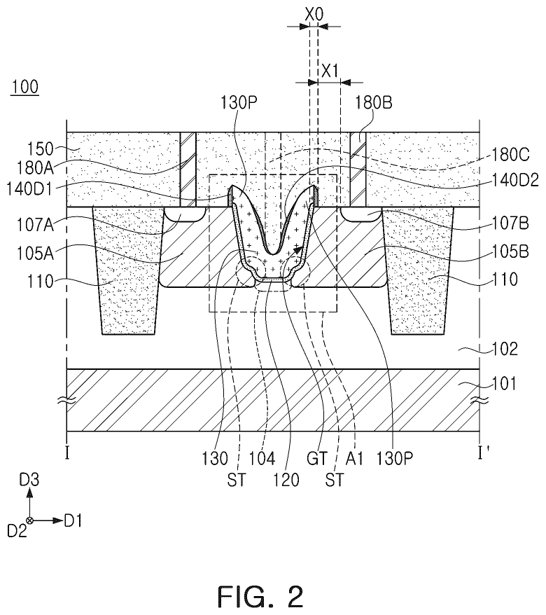

FIG. 1 is a plan view illustrating a high voltage semiconductor device according to some example embodiments, and FIG. 2 is a cross-sectional view taken along line I-I′ of the high voltage semiconductor device illustrated in FIG. 1. In FIG. 1 the interlayer insulating layer 150 of FIG. 2 may be omitted for sake of clarity of illustration.

Referring to FIG. 1 and FIG. 2, a high voltage semiconductor device 100 according to some example embodiments may include a substrate 101, a well region 102 of a first conductivity-type in the substrate 101, first and second drift regions 105A and 105B of a second conductivity-type facing each other in a first direction D1 in the well region 102, and a buried gate electrode 130 between the first and second drift regions 105A and 105B.

The substrate 101 may include, for example, a semiconductor such as Si or Ge, or a compound semiconductor such as SiGe, SiC, GaAs, InAs, or InP. In some example embodiments, the substrate 101 may have a silicon on insulator (SOI) structure. The substrate 101 may include first conductivity-type impurities, and thus may have a first conductivity-type. In some example embodiments, the first conductivity-type may be, for example, P-type, and the first conductivity-type impurities may be, for example, P-type impurities, such as aluminum (Al). In some example embodiments, the first conductivity-type may be, for example, N-type, and the first conductivity-type impurities may be, for example, N-type impurities, such as nitrogen (N) and/or phosphorus (P).

An element isolation region 110 may be formed in the substrate 101 to define an active region for the high voltage semiconductor device 100. The first and second drift regions 105A and 105B may be disposed on both sides of the active region defined by the element isolation region 110, respectively. As illustrated in FIG. 1, the element isolation region 110 may extend in the second direction D2 intersecting the first direction D1. The element isolation region 110 may include an insulating material of silicon oxide or silicon oxide series filled in a trench formed in the well region 102. For example, the element isolation region 110 may also be referred to as Shallow Trench Isolation (STI).

The well region 102 may include first conductivity-type impurities and thus may have first conductivity-type. The well region 102 may also be referred to as a ‘high-voltage well region.’ In some example embodiments, the first conductivity-type may be, for example, P-type, and the first conductivity-type impurities may be, for example, P-type impurities such as aluminum (Al). In some example embodiments, the first conductivity-type may be, for example, N-type, and the first conductivity-type impurities may be, for example, N-type impurities such as nitrogen (N) and/or phosphorus (P). In some example embodiments, the well region 102 may be formed by implanting into the substrate 101 through a mask such as a photoresist pattern.

The first and second drift regions 105A and 105B include second conductivity-type impurities and thus may have second conductivity-type. The first and second drift regions 105A and 105B may be exposed from the upper surface of the substrate 101 (or, alternatively from the upper surface of the well region 102). As illustrated in FIG. 1, the first and second drift regions 105A and 105B may extend in the second direction D2. In some example embodiments, the second conductivity-type may be, for example, N-type, and the second conductivity-type impurities may be, for example, N-type impurities such as nitrogen (N) and/or phosphorus (P). In some example embodiments, the second conductivity-type may be, for example, P-type, and the second conductivity-type impurities may be, for example, P-type impurities such as aluminum (Al). In some example embodiments, the first and second drift regions 105A and 105B may be formed by implanting into both sides of the well region 102 through a mask such as a photoresist pattern.

The buried gate electrode 130 may be formed in the gate trench GT between the first and second drift regions 105A and 105B. The gate trench GT may be formed by an etching process using a photolithography process. In some example embodiments, the gate trench GT may be formed after the first and second drift regions 105A and 105B are formed. The bottom of the gate trench GT may be provided or defined by the well region 102, and two sidewalls of the gate trench GT may be provided or defined by the first and second drift regions 105A and 105B. The sidewalls of the gate trench GT may be provided or defined by the first and second drift regions 105A and 105B over almost the entire area.

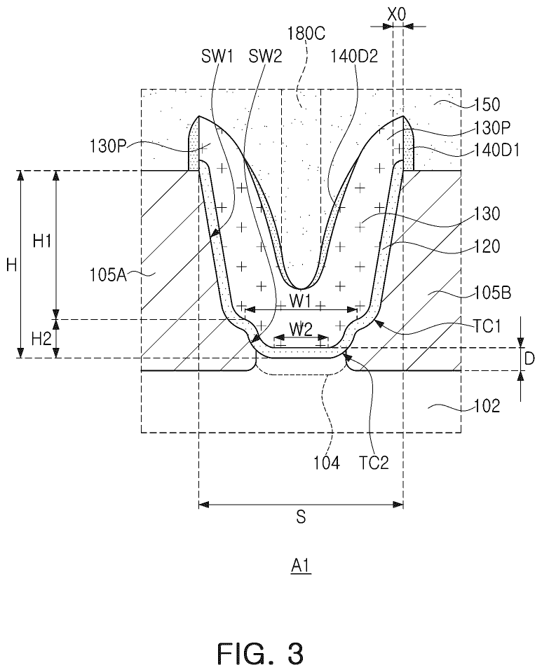

The two sidewalls of the gate trench GT employed in some example embodiments may have a step ST (or a step feature). FIG. 3 is a partial enlarged view illustrating a portion A1 of the high voltage semiconductor device 100 illustrated in FIG. 2.

Referring to FIG. 3 together with FIG. 2, the sidewall of the gate trench GT may have an inclined surface based on (or with reference to) the bottom of the gate trench GT (or the upper surface of the substrate 101). The inclined sidewalls of the gate trench GT may be divided into an upper sidewall SW1 and a lower sidewall SW2 by the step ST. The height H1 of the upper sidewall SW1 may be greater than the height H2 of the lower sidewall SW2. For example, the height H1 of the upper sidewall SW1 may be in the range of 0.2 μm (or about 0.2 μm) to 0.5 μm (or about 0.5 μm), and the height H2 of the lower sidewall SW2 may be in the range of 0.05 μm (or about 0.05 μm) to 0.2 μm (or about 0.2 μm). The height H2 of the lower sidewall SW2 may be 30% or less of the total depth H of the gate trench GT. In some example embodiments, the height H2 of the lower sidewall SW2 may be 20% or less of the total depth H of the gate trench GT.

Due to the step ST, the bottom corner of the gate trench GT may be a two-step corner structure. In some example embodiments, by forming the bottom corner of the gate trench GT, where the current and electric field are relatively concentrated, as a two-step structure, the concentrated current and electric fields may be dispersed. This two-step corner structure may not only lower the breakdown voltage in the ON state, but also reduce the injection of hot carriers.

In some example embodiments, the two-step corner structure of the gate trench GT may include a lower corner TC2 adjacent to the bottom of the gate trench GT, and an upper corner TC1 on the lower corner TC2. The lower corner TC2 connects the lower sidewall SW2 and the bottom of the gate trench GT, and the upper corner TC1 may be located at the lower end of the upper sidewall SW1. As described above, the sidewall of the gate trench GT has an inclined surface, and the width W2 in the first direction D1 between the lower corners TC2 may be smaller than the width W1 in the first direction D1 between the upper corners TC1. The lower sidewall SW2 may have a generally inclined surface similar to the upper sidewall SW1.

In some example embodiments, the lower corner TC2 may have a rounded structure (or curved), as illustrated in FIG. 3. If the lower corner TC2 is angled (e.g., defines a corner or an edge, as opposed to a curvature) , the drain current may be reduced because the electron mobility may be reduced in the adjacent drift regions 105A and 105B. The rounded lower corner TC2 according to some example embodiments may not reduce the drain current. In some example embodiments, the upper corner TC2 may also have a similarly rounded structure.

At least a portion of the upper corner TC1 may be formed to be covered by the first and second drift regions 105A and 105B. In some example embodiments, the upper corner TC1 may be covered by the first and second drift regions 105A and 105B, and further, at least a portion of the lower corner TC2 may be covered by the first and second drift regions 105A and 105B.

In some example embodiments, the bottom of the gate trench GT may be substantially at a level of the lower surfaces of the first and second drift regions 105A and 105B or may be at a level higher than the lower surfaces of the first and second drift regions 105A and 105B. Accordingly, the bottom of the gate electrode 130 in the gate trench GT may have a level same (or equal) as or higher than the lower surfaces of the first and second drift regions 105A and 105B. In some example embodiments, the bottom of the gate electrode 130 may be higher than the lower surfaces of the first and second drift regions 105A and 105B, by an amount indicated by “D”. For example, the depth H of the gate trench GT may be 0.3 μm to 0.6 μm, and the width S of the gate trench GT may be 0.4 μm to 0.8 μm.

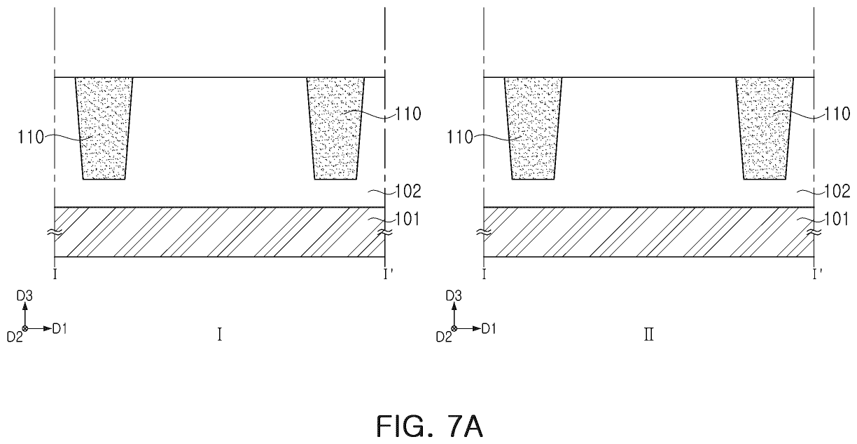

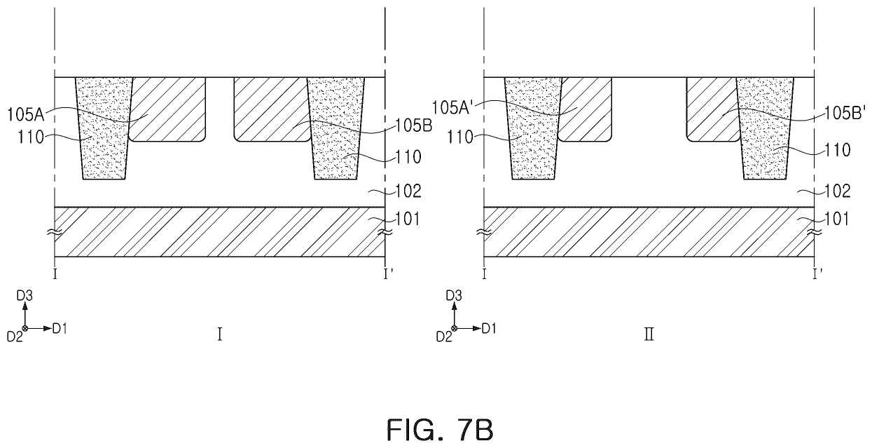

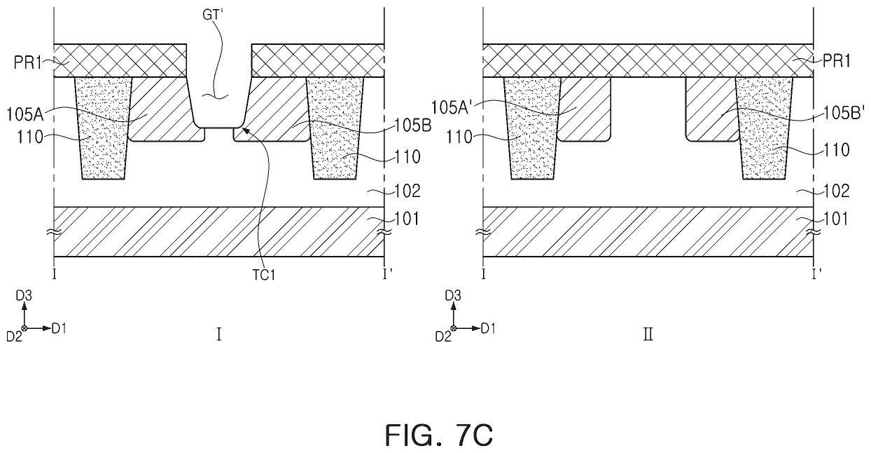

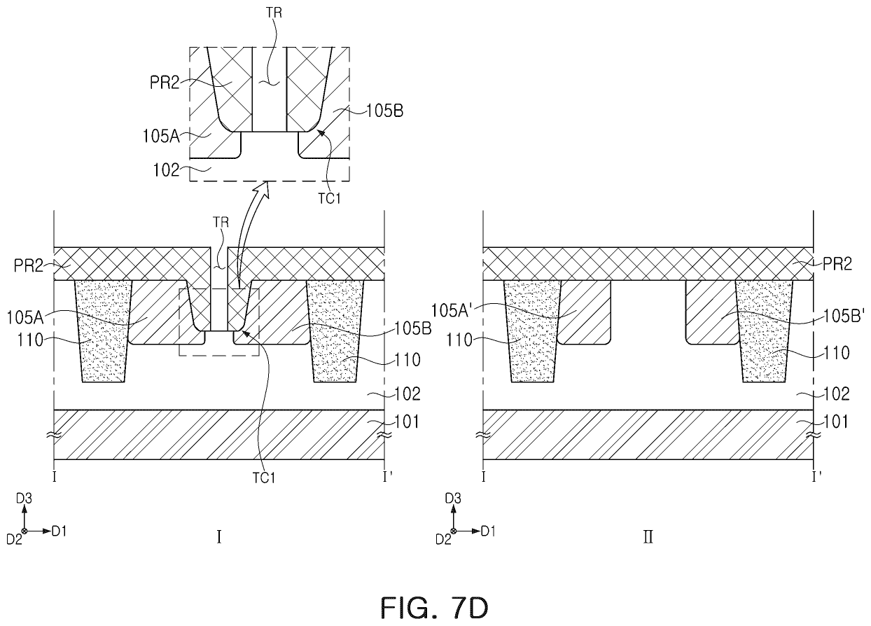

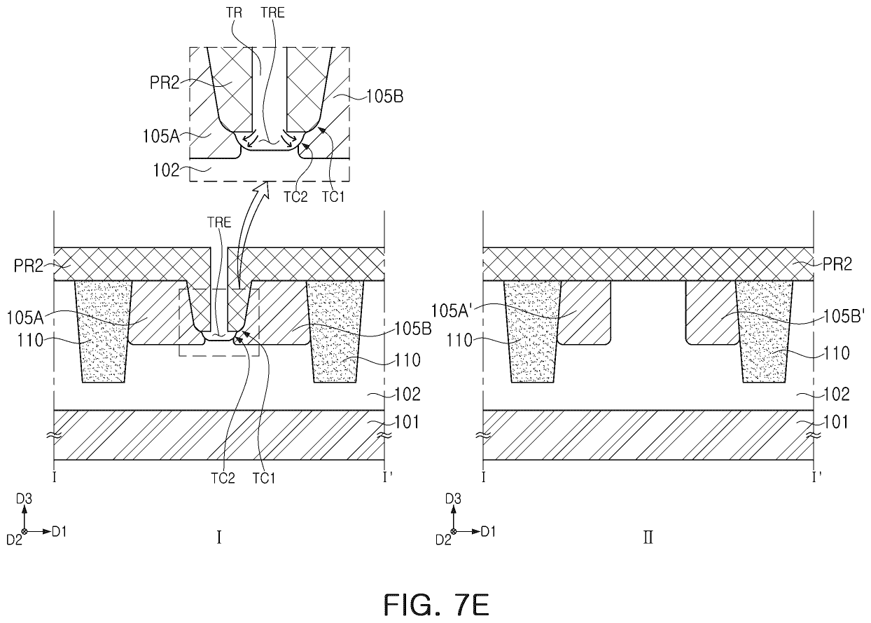

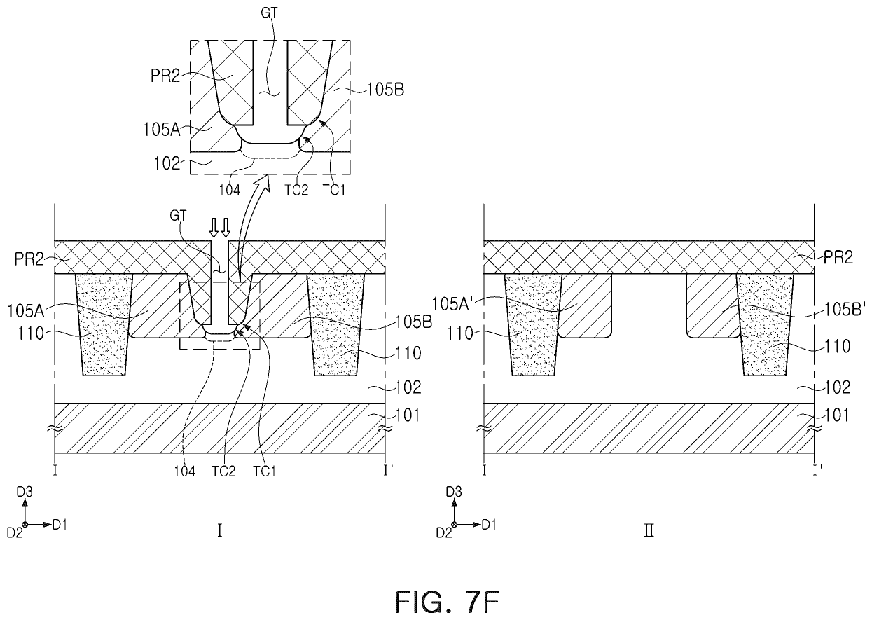

A high-concentration channel region 104 may be formed in the well region 102 at the bottom of the gate trench GT. The high-concentration channel region 104 may be defined as a region between the lower corners TC2. In some example embodiments, the high-concentration channel region 104 may be obtained by an ion implantation process using a mask for forming the gate trench GT without using an additional mask (see FIG. 7F). The high-concentration channel region 104 may be additionally implanted with impurities to control a threshold voltage. For example, the high concentration channel region 104 may have an impurity concentration higher than an impurity concentration of the well region 102 in a region defined by the bottom of the gate trench GT in the well region 102.

The gate insulating film 120 may be conformally formed to cover the inner surface of the gate trench GT, for example, the bottom and two sidewalls. In some example embodiments, the gate insulating film 120 may extend to the upper end of the sidewall of the gate trench GT. The gate insulating film 120 may include, for example, silicon oxide, silicon oxynitride, a high-κ dielectric, combinations thereof, or a laminated film thereof. The high-κ dielectric may include HfO₂, ZrO₂, Al₂O₃, Ta₂O₅, hafnium silicate, zirconium silicate, or combinations thereof. When the gate insulating film 120 is silicon oxide, the silicon oxide may be formed by an oxidation process such as a thermal oxidation process, but is not limited thereto, and the gate insulating film 120 may also be formed by chemical vapor deposition (CVD), atomic layer deposition (ALD), physical vapor deposition (PVD), or combinations thereof. For example, the gate insulating film 120 may have a thickness of 100 Å to 500 Å.

The gate electrode 130 may be buried in the gate trench GT and may be disposed on the gate insulating film 120. For example, the gate electrode 130 may include polysilicon. The polysilicon may be doped with N-type or P-type impurities. In some example embodiments, the gate electrode 130 may include a metal such as tungsten. The gate electrode 130 may be deposited by chemical vapor deposition (CVD) or physical vapor deposition (PVD).

In the gate electrode 130 according to some example embodiments, in a planar view, the gate electrode extends in the second direction D2 between the first and second drift regions 105A and 105B, and the upper surface of the gate electrode 130 may define a valley (e.g., a concavity, or a depression in the gate electrode 130) extending in the second direction D2. The gate electrode 130 may have extended portions 130P that extend onto the first and second drift regions 105A and 105B adjacent to the gate trench GT. For example, the width of each of the extended portions 130P of the gate electrode 130 may be 0.2 μm or less. In some example embodiments, the gate electrode 130 may be formed only in the gate trench GT.

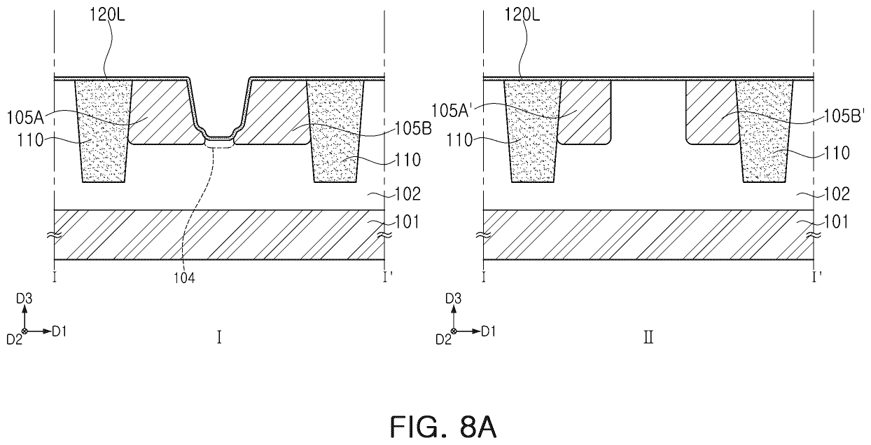

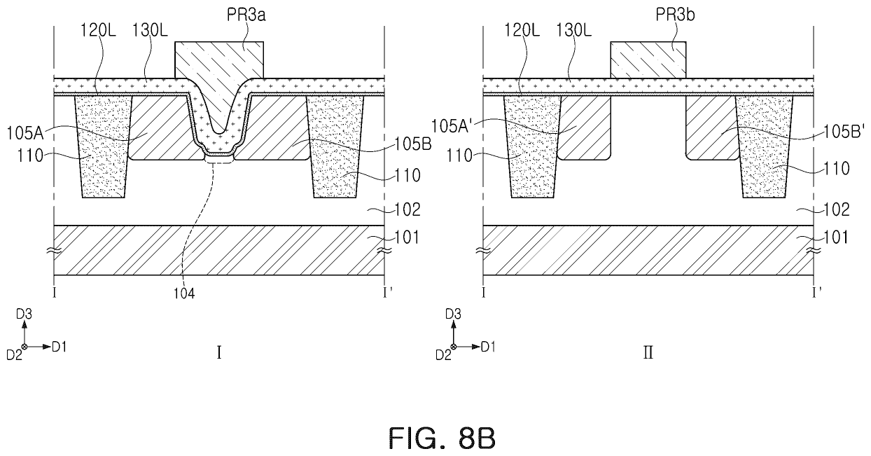

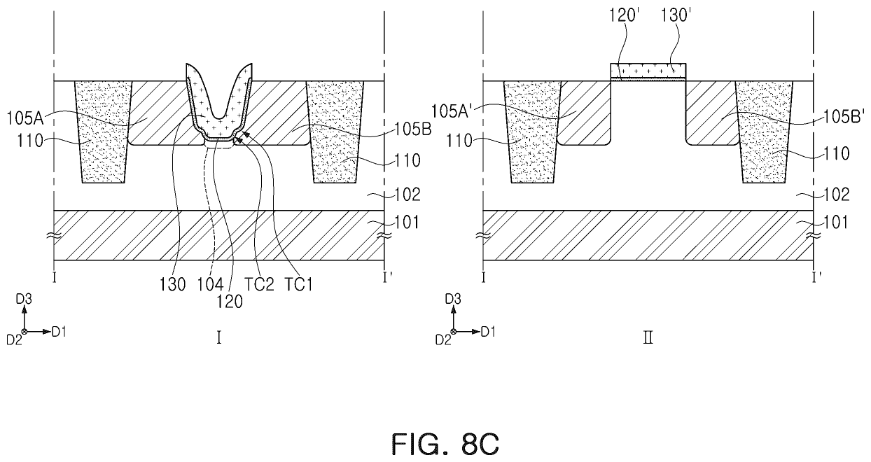

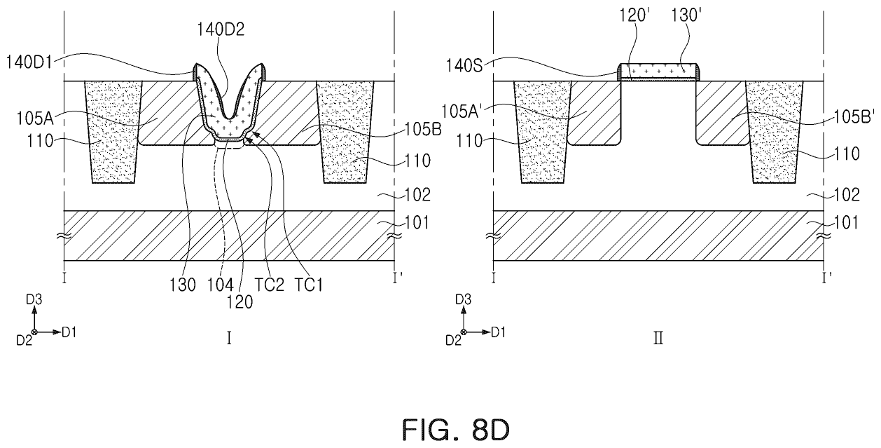

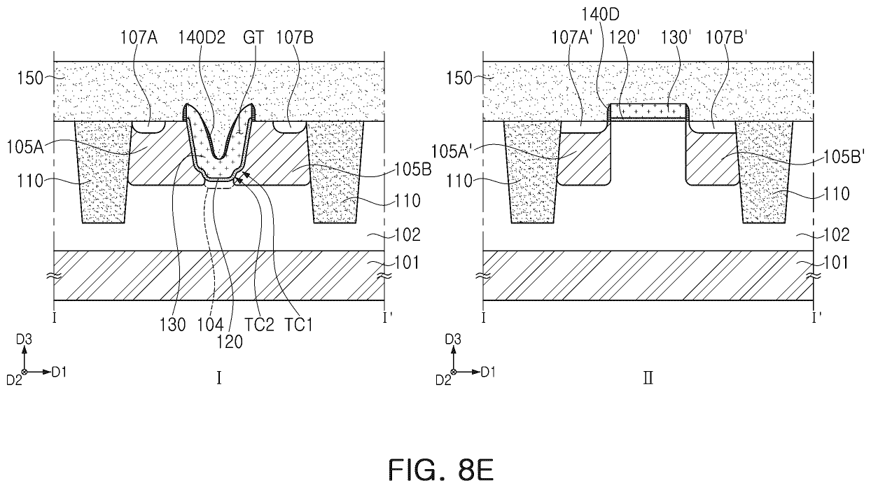

The first and second residual spacer materials 140D1 and 140D2 may be formed around the gate electrode 130. The first residual spacer material 140D1 may be disposed on the sidewall of the extended portions 130P of the gate electrode 130, and the second residual spacer material 140D2 may be disposed on the sidewall along the concave valley of the gate electrode 130. The first and second residual spacer materials 140D1 and 140D2 may be spacer materials that remain in the process of forming the gate spacer of the MOSFET element in another region of the substrate 101 (see FIG. 8D). For example, the first and second residual spacer materials 140D1 and 140D2 may include silicon nitride or silicon oxynitride.

Referring to FIGS. 1 and 2, the source/drain regions 107A and 107B may be disposed on the first and second drift regions 105A and 105B, respectively. The source/drain regions 107A and 107B may have an impurity concentration higher than the impurity concentrations of the first and second drift regions 105A and 105B. The plurality of source/drain regions 107A and 107B have a same second conductivity-type as the first and second drift regions 105A and 105B. The plurality of source/drain regions 107A and 107B may be arranged in the second direction D2 in the first and second drift regions 105A and 105B. The plurality of source/drain regions 107A and 107B may be formed by implanting a second conductivity-type impurity into the first and second drift regions 105A and 105B through a mask, such as a photoresist pattern. In some example embodiments, the plurality of source/drain regions 107A and 107B may be connected to each other at the first and second drift regions 105A and 105B and configured in a line type.

The plurality of source/drain regions 107A and 107B are formed from the surfaces of the first and second drift regions 105A and 105B and may have a thickness thinner than the thicknesses of the first and second drift regions 105A and 105B. As illustrated in FIG. 2, the source/drain regions 107A and 107B may be formed to be spaced apart from the extended portions 130P of the gate electrode 130 by a desired or given distance X1. The arrangement of the source/drain regions 107A and 107B may improve the breakdown voltage characteristics. For example, the distance X1 between the source/drain regions 107A and 107B and the extended portions 130P may be 0.2 μm to 1 μm.

Referring to FIG. 2, the high voltage semiconductor device 100 according to some example embodiments may further include an interlayer insulating layer 150 covering the first and second drift regions 105A and 105B and the gate electrode 130 on the substrate 101, and a plurality of first and second contact plugs 180A and 180B penetrating the interlayer insulating layer 150 and electrically connected to the first and second drift regions 105A and 105B, respectively. For example, the plurality of first and second contact plugs 180A and 180B may include at least one of nickel (Ni), aluminum (Al), titanium (Ti), silver (Ag), vanadium (V), tungsten (W), cobalt (Co), molybdenum (Mo), copper (Cu), and ruthenium (Ru). In some example embodiments, the source/drain regions in contact with the plurality of first and second contact plugs 180A and 180B may include a metal-semiconductor compound layer (not illustrated) to lower the contact resistance. For example, the metal-semiconductor compound layer may include at least one of TiSi, CoSi, MoSi, LaSi, NiSi, TaSi, or WSi.

Referring to FIG. 1, the plurality of first and second contact plugs 180A and 180B may be arranged in the second direction D2. A plurality of first and second contact plugs 180A and 180B are connected to the source/drain regions 107A and 107B, respectively, and may be electrically connected to the first and second drift regions 105A and 105B through the source/drain regions 107A and 107B. Similar to the first and second contact plugs 180A and 180B, a third contact plug 180C may be connected to the gate electrode 130 at any desired location on the gate electrode 130 by penetrating the interlayer insulating layer 150.

The technical effect according to some example embodiments, may be observed based on the electrical characteristics due to different gate structures of high voltage semiconductor device of a comparative example and high voltage semiconductor device of some example embodiment.

It may be understood that the high voltage semiconductor devices according to the comparative example and example embodiment have same or similar specifications and the shape of the gate trench and the gate structure according to the gate trench may be different.

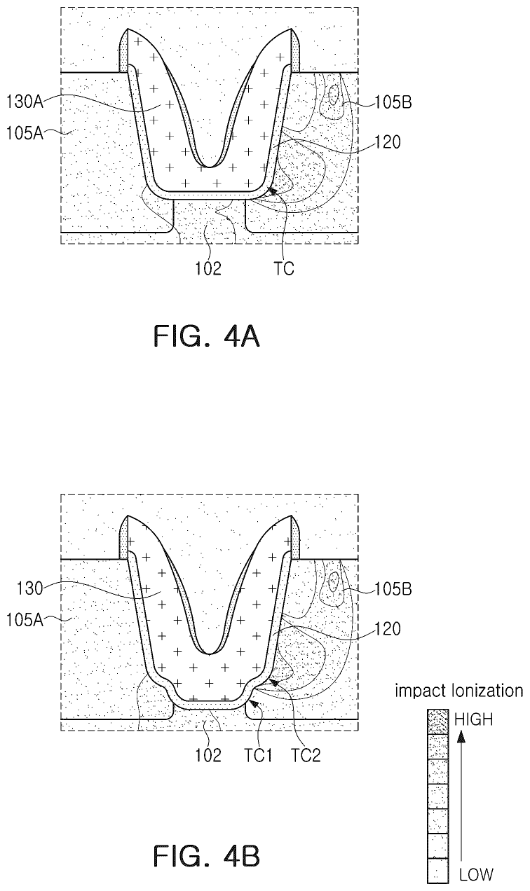

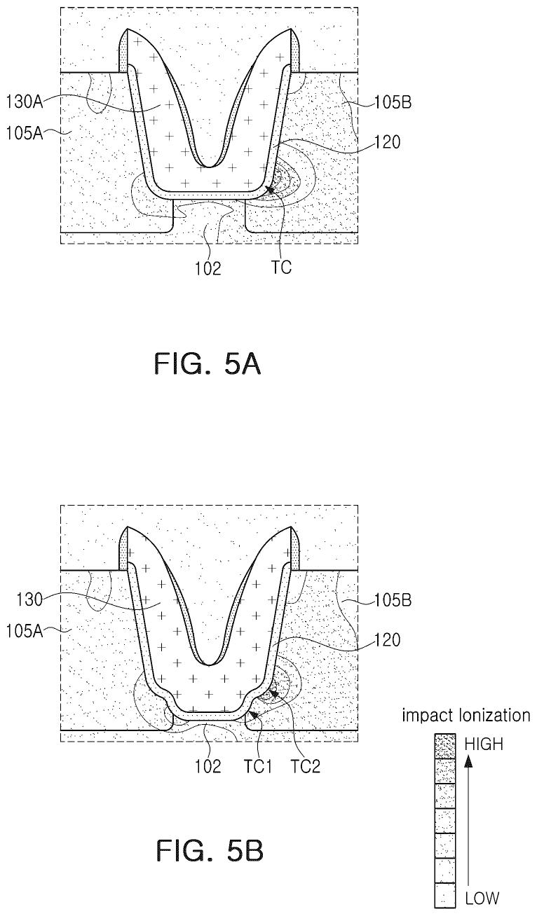

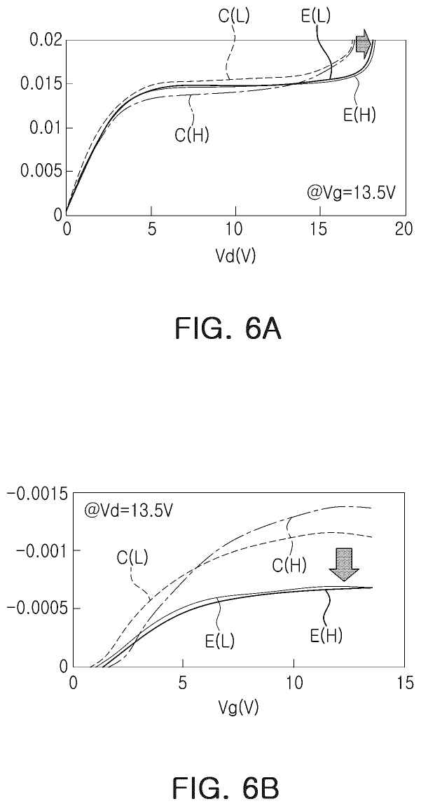

FIGS. 4A and 4B and FIGS. 5A and 5B illustrate impact ionization in high voltage semiconductor devices (comparative example and some example embodiments) for different gate structures, and FIGS. 6A and 6B illustrate I-V curves of the high voltage semiconductor devices according to the comparative example and example embodiment for different operating voltage conditions (for example, on-state), respectively.

First, the high voltage semiconductor devices (comparative example) of FIGS. 4A and 5A have a gate electrode 130A whose gate trench GT has a slanted or inclined sidewall without a step, whereas the high voltage semiconductor devices (example embodiments) of FIGS. 4B and 5B have a slanted or inclined sidewall of the gate trench GT with a step. The gate trench GT in FIGS. 4B and 5B has a two-step bottom corner structure including an upper corner TC1 and a lower corner TC2.

FIGS. 4A and 4B and FIGS. 5A and 5B illustrate the impact ionization degrees of respective elements in the ON state, respectively. FIGS. 4A and 4B illustrate impact ionization degrees in high voltage semiconductor devices according to the comparative example and example embodiment, respectively, when the gate voltage Vg is applied at 13.5 V, and FIGS. 5A and 5B illustrate impact ionization degrees in high voltage semiconductor devices according to the comparative example and example embodiment, respectively, when the gate voltage Vg and drain voltage Vd are simultaneously applied at 13.5 V.

In the ON state, in the high voltage semiconductor device according to comparative examples (see FIGS. 4A and 5A), impact ionization occurs relatively strongly at the bottom corner of the gate trench GT where the current density and electric field are concentrated, whereas in the high voltage semiconductor device according to some example embodiments (see FIGS. 4B and 5B), the electric field and current density may be dispersed by introducing a two-step bottom corner.

Referring to FIG. 6A, when the gate voltage Vg is applied, the drain current Id changes according to the drain voltage Vd of the high voltage semiconductor devices according to some example embodiment and the comparative example is illustrated, and the results according to the threshold voltage Vt size are illustrated separately in the example embodiment and the comparative example. The results of the example embodiment and the comparative example at high threshold voltage are illustrated as EH and CH, respectively, and the results of the example embodiment and the comparative example at low threshold voltage are illustrated as E(L) and C(L), respectively.

Referring to FIG. 6A, as illustrated by the arrow, a high voltage semiconductor device according to some example embodiments may improve breakdown voltage characteristics in the ON state compared to the high voltage semiconductor device according to the comparative example. This technical effect may be obtained by the high voltage semiconductor device according to some example embodiments by introducing a two-step bottom corner to disperse the electric field and current density to the upper and lower corners.

Referring to FIG. 6B, when the drain voltage Vd is applied together with the gate voltage Vg, the substrate current Isub of the high voltage semiconductor devices according to the example embodiment and the comparative example is illustrated according to the gate voltage Vg, and the results according to the size of the threshold voltage Vt are illustrated separately in the example embodiment and the comparative example. The results of the example embodiment and the comparative example at high threshold voltage are illustrated as EH and CH, respectively, and the results of the example embodiment and the comparative example at low threshold voltage are illustrated as E(L) and C(L), respectively.

Referring to FIG. 6B, as illustrated by the arrow, it may be observed that the substrate current Isub of the high voltage semiconductor device according to example embodiment is reduced compared to the high voltage semiconductor device according to the comparative example. This technical effect may be as the result of the high voltage semiconductor device according to some example embodiments reducing the carriers generated due to impact ionization by introducing a two-step bottom corner, thereby reducing ‘hot carrier injection (HCl)’.

FIGS. 7A to 7F are cross-sectional views of some processes in a method of manufacturing a high voltage semiconductor device according to some example embodiments. The process according to some example embodiments may simultaneously form a high voltage semiconductor device 100 of FIGS. 1 to 3 and another planar MOSFET element in the first region I and the second region II, respectively, of one (single) substrate 101.

Referring to FIG. 7A, a first conductivity-type well region 102 may be formed on the first region I and the second region II of the substrate 101, and an element isolation region 110 defining an active region may be formed in the first conductivity-type well region 102.

The substrate 101 introduced in some example embodiments may include, for example, a semiconductor such as Si or Ge, or a compound semiconductor such as SiGe, SiC, GaAs, InAs, or InP. In some example embodiments, the substrate 101 may have a silicon on insulator (SOI) structure. The substrate 101 may be a first conductivity-type substrate including first conductivity-type (for example, P-type) impurities. Then, by injecting first conductivity-type impurities into the first region I and the second region II of the substrate 101 through a mask such as a photoresist pattern, a first conductivity-type well region 102 may be formed. In the second region II, when a low-voltage MOSFET or another conductivity-type MOSFET is formed, a well region with a different impurity concentration or a well region with a different conductivity-type impurity concentration may be formed in the second region II using an additional mask.

Element isolation regions 110 may be formed in the first region I and the second region II of the substrate 101, respectively, to define an active region for forming a device (for example, a MOSFET). The element isolation regions 110 may be extended along the second direction D2 intersecting the first direction D1. As a result, an active region extending in the second direction D2 may be provided in each of the first region I and the second region II of the substrate 101. In some example embodiments, the element isolation regions 110 may be formed differently in a planar view to form semiconductor devices having different layouts.

Next, referring to FIG. 7B, the first and second drift regions 105A and 105B, and 105A′ and 105B′ may be formed in the first region I and the second region II of the substrate 101, respectively.

The first and second drift regions 105A, 105B, 105A′ and 105B′ may be formed by injecting a second conductivity-type impurity into both sides of respective active regions (for example, the well regions 102) of the first region I and the second region II of the substrate 101, respectively, using a mask such as a photoresist pattern. In the first region I of the substrate 101, the first and second drift regions 105A and 105B may extend along the second direction D2, as illustrated in FIG. 1. Similarly, in the second region II of the substrate 101, the first and second drift regions 105A′ and 105B′ may extend along the second direction D2.

In some example embodiments, as described above, the first and second drift regions 105A, 105B, 105A′ and 105B′ may have different layouts according to the pattern of the active region defined by the element isolation region 110.

Referring to FIG. 7C, a first gate trench GT′ may be formed in the first region I of the substrate 101 using a first photoresist pattern PR1.

The first photoresist pattern PR1 may have an opening defining the first gate trench GT′ in the first region I of the substrate 101 and may be formed to entirely cover the second region II of the substrate 101. The first gate trench GT′ may be formed by an etching process using the first photoresist pattern PR1.

The first gate trench GT′ may be formed after the first and second drift regions 105A and 105B are formed. In some example embodiments, the first gate trench GT′ may be extended in the second direction D2. By controlling the position and width of the first gate trench GT′, the first and second drift regions 105A and 105B may form the two sidewalls of the first gate trench GT′.

In some example embodiments, the first gate trench GT′ may be formed to a depth of a portion (for example, 70% to 90%) of the final depth of the required gate trench. The bottom of the first gate trench GT′ may be sufficiently higher than the lower surface of the first and second drift regions 105A and 105B. In some example embodiments, the sidewall of the first gate trench GT′ may have an inclined surface.

Next, referring to FIG. 7D, after the first photoresist pattern PR1 is removed, a second photoresist pattern PR2 may be formed to form a final gate trench GT having a step.

The second photoresist pattern PR2 may have an opening TR in the first region I of the substrate 101 similarly to the first photoresist pattern PR1 and may be formed to entirely cover the second region II of the substrate 101. The opening TR of the second photoresist pattern PR2 may be formed to have a narrower width than the width of the first gate trench GT′ in the first direction D1. In addition, the opening TR of the second photoresist pattern PR2 is formed so that a part of the bottom region of the first gate trench GT′ is open.

Next, referring to FIG. 7E, a gate trench GT may be formed in the first region I of the substrate 101 using a second photoresist pattern PR2.

This process may be performed by a wet etching process on the bottom region of the first gate trench GT′ exposed by the opening TR. As illustrated in the enlarged view indicated by the arrow, the exposed bottom region is etched almost isotropically, so that not only the depth of the first gate trench GT′ is expanded, but also partial etching may be performed below the second photoresist pattern PR2. By this wet etching process, a gate trench GT having a 2-step corner structure having an upper corner TC1 and a lower corner TC2 may be formed. The lower corner TC2 may have a rounded structure by the wet etching process.

A well region 102 that may be provided as a channel region may be opened at the bottom of the gate trench GT obtained by the present process. In some example embodiments, the bottom of the gate trench GT may be at or about a same level as or a level higher than the lower surface of the first and second drift regions 105A and 105B. For example, the lower corner TC2 of the gate trench GT may be at least partially covered by the first and second drift regions 105A and 105B.

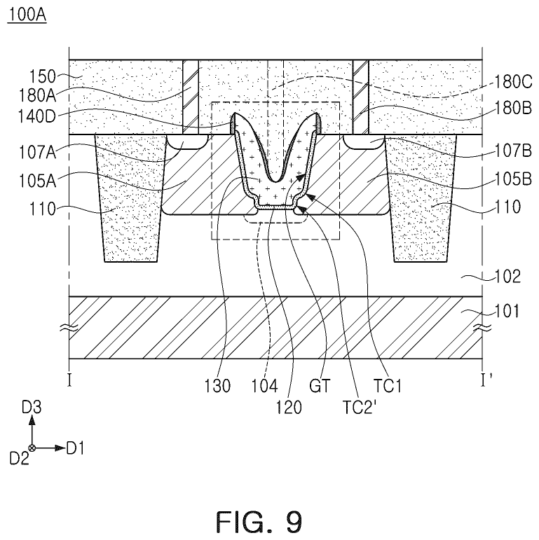

In some example embodiments, a 2-step corner structure is formed by a wet etching process, but example embodiments are not limited thereto, and in some example embodiments, a 2-step corner structure may be obtained by using a dry etching process. However, in this case, the lower corner may have a relatively sharper corner (or edge) (see FIG. 9).

Next, referring to FIG. 7F, an ion implantation process may be performed on the bottom of the gate trench GT using the second photoresist pattern PR2.

This ion implantation process may control the threshold voltage of the channel region 104. For example, a first conductivity-type impurity may be additionally implanted in this process. The second photoresist pattern PR2 used to form the final gate trench GT in this ion implantation process may be used as is. A channel region 104 with a controlled threshold voltage may be formed at the bottom of the gate trench GT.

FIGS. 8A to 8E are cross-sectional views of processes in a method of manufacturing a high voltage semiconductor device according to some example embodiments.

Referring to FIG. 8A, after removing the second photoresist pattern PR2 (FIG. 7F), a gate insulating film 120L may be formed in the first region I and the second region II of the substrate 101.

In the first region I of the substrate 101, the gate insulating film 120L may be conformally formed to cover the inner surface of the gate trench GT, for example, the bottom and two sidewalls. For example, the gate insulating film 120L may include silicon oxide, silicon oxynitride, a high-κ dielectric, combinations thereof, or a laminated film thereof. The high-κ dielectric may include HfO₂, ZrO₂, Al₂O₃, Ta₂O₅, hafnium silicate, zirconium silicate, or combinations thereof.

In some example embodiments, the same gate insulating film 120L is formed in both the first region I and the second region II of the substrate 101, but a gate insulating film different from the gate insulating film of the first region I may be formed in the second region II. For example, in the case of forming a low-voltage MOSFET in the second region II of the substrate 101, a gate insulating film of a different material and/or a different number of layers may be formed in the second region II using an additional mask.

Next, referring to FIG. 8B, a conductive material layer 130L for a gate electrode may be formed on the first region I and the second region II of the substrate 101, and then third photoresist patterns PR3a and PR3b may be formed in some regions of the conductive material layer 130L in the first region I and the second region II of the substrate 101.

First, the conductive material layer 130L may fill the gate trench GT in the first region I of the substrate 101. The conductive material layer 130L may include polysilicon. The polysilicon may be doped with an N-type or P-type impurity. In some example embodiments, the conductive material layer 130L may include a metal such as tungsten. The conductive material layer 130L may be deposited by chemical vapor deposition (CVD) or physical vapor deposition (PVD). Then, the third photoresist patterns PR3a and PR3b may define portions corresponding to the gate electrode in the conductive material layer 130L.

A third photoresist pattern PR3a defining a gate electrode 130 may be formed on a portion of the conductive material layer 130L in the first region I of the substrate 101. A third photoresist pattern PR3b defining a gate electrode 130′ may be formed on a portion of the conductive material layer 130L in the second region II of the substrate 101.

Next, referring to FIG. 8C, by etching the conductive material layer 130L in the first region I and the second region II of the substrate 101 using the third photoresist patterns PR3a and PR3b, the gate electrodes 130 and 130′ and the gate insulating films 120 and 120′ may be formed.

In this process, the gate electrodes 130 and 130′ and the gate insulating films 120 and 120′ may be formed in the first region I and the second region II of the substrate 101, respectively. In the first region I of the substrate 101, the gate electrode 130 may be formed by selectively etching the conductive material layer 130L using the third photoresist pattern PR3a, and similarly, in the second region II of the substrate 101, the gate electrode 130′ may be formed using the third photoresist patterns PR3b.

Additionally, during the main etching process or after performing the etch-back process, the gate insulating films 120 and 120′ may be formed in the first region I and the second region II of the substrate 101, respectively, by removing the exposed gate insulating film portions through an additional etching process.

Next, referring to FIGS. 8D and 8E, a gate spacer 140S may be formed on the sidewall of the gate electrode 130′ in the second region II of the substrate 101.

The process of forming the gate spacer 140S may be performed by forming a spacer material layer over the first region I and the second region II of the substrate 101, and applying anisotropic etching to remove portions of the spacer material layer from surfaces parallel to the upper surface of the substrate 101.

In the process of forming the gate spacer 140S, first and second residual spacer materials 140D1 and 140D2 may be formed on the sidewalls of the gate electrode 130 in the first region I of the substrate 101.

Additionally, source/drain regions 107A and 107B, and 107A′ and 107B′ may be formed in the first and second drift regions 105A and 105B, and 105A′ and 105B′ in the first region I and the second region II of the substrate 101, respectively. The source/drain regions 107A, 107B, 107A′ and 107B′ may have an impurity concentration higher than the impurity concentrations of the first and second drift regions 105A, 105B, 105A′ and 105B′.

Next, an interlayer insulating layer 150 may be formed on the first region I and the second region II of the substrate 101 (see FIG. 8E). Next, contact holes connected to the source/drain regions 107A, 107B, 107A′, and 107B′ may be formed in the interlayer insulating layer 150. In a subsequent process, a conductive material is filled in the contact holes, and then chemical mechanical polishing (CMP) is applied until the upper surface of the interlayer insulating layer 150 is exposed to remove the conductive material remaining on the interlayer insulating layer 150. As a result, a high voltage semiconductor device 100 (or a high voltage MOSFET) as illustrated in FIGS. 1 to 3 is provided in the first region I of the substrate 101, and a MOSFET 200 of a planar structure may be formed in the second region II of the substrate 101.

FIG. 9 is a cross-sectional side view illustrating a high voltage semiconductor device according to some example embodiments.

Referring to FIG. 9, a high voltage semiconductor device 100A according to some example embodiments may be as same or similar in some respects to the high voltage semiconductor device 100 illustrated in FIGS. 1 to 3. In the high voltage semiconductor device 100A the lower corner may include an angled (or edged, cornered) structure. The high voltage semiconductor device 100A of FIG. 9 may be best understood by referring to the description of the high voltage semiconductor device 100 illustrated in FIGS. 1 to 3 where like numerals indicate like elements not described again in detail.

In some example embodiments, the lower corner TC2′ may have an angled (or cornered, or edged) structure. The angled lower corner TC2′ also reduces the drain current because the electron mobility in the adjacent drift regions 105A and 105B is reduced, and the breakdown voltage characteristics and hot carrier injection characteristics in the On state may be improved by dispersing the current and electric field through the lower corner together with the upper corner.

The angled lower corner TC2′ may be obtained by performing dry etching instead of wet etching in the etching process of FIG. 7C. When dry etching is performed, the opening TR of the second photoresist pattern PR2 introduced in FIG. 7B may be formed to have a relatively large width.

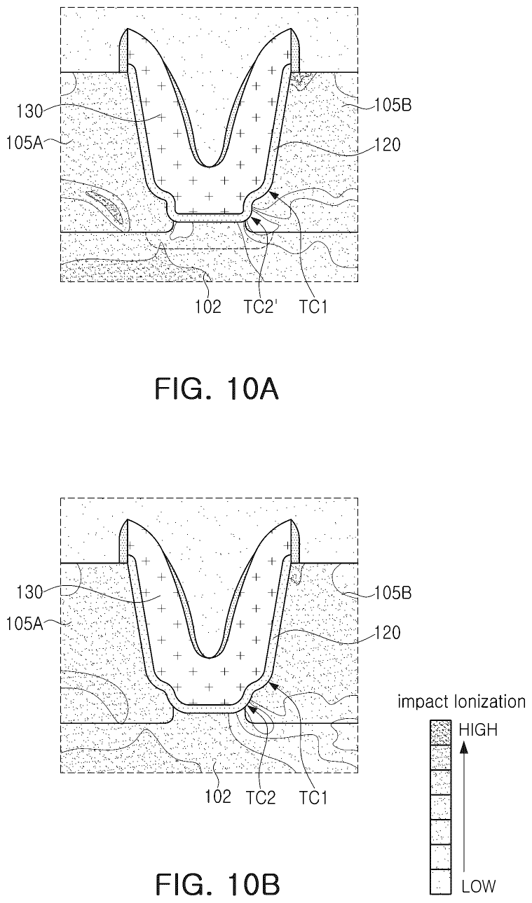

FIGS. 10A and 10B illustrate impact ionization degrees in high voltage semiconductor devices (Examples 1 and 2) for different gate structures.

The high voltage semiconductor devices according to Examples 1 and 2 both include gate trenches with a 2-step corner structure, but the high voltage semiconductor device according to Example 1 has a structure with an angled lower corner similar to the high voltage semiconductor device 100A illustrated in FIG. 9, while the high voltage semiconductor device according to Example 2 has a structure with a rounded lower corner similar to the high voltage semiconductor device 100 illustrated in FIG. 2. This difference in the lower corner may be determined depending on the type of etching process introduced in FIG. 7E.

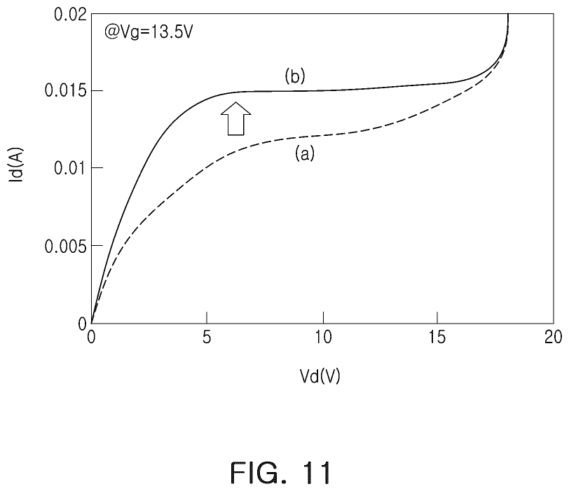

Referring to FIGS. 10A and 11, in the 2-step corner structure, the lower corner TC2, has a lower electron mobility in the adjacent drift region, and thus the drain current decreases. On the other hand, referring to FIGS. 10B and 11, the high voltage semiconductor device according to Example 2 has a lower corner of a round structure, and thus may maintain a higher drain current than Example 1 without a decrease in electron mobility.

In this way, by using a wet etching process in the second etching process (the process of FIG. 7E) for forming the lower corner, the lower corner may be formed as a round structure, and a relatively higher drain current may be obtained around the lower corner.

As set forth above, according to some example embodiments described above, by introducing a corner structure in which the corner adjacent to the bottom of a gate trench is composed of two steps in a high voltage semiconductor device, not only may breakdown voltage characteristics in the ON state be improved, but also a hot carrier injection effect may be reduced, thereby improving reliability.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A high voltage semiconductor device comprising:
a substrate;
a well region of a first conductivity-type in the substrate;
a first drift region and a second drift region each of a second conductivity-type in the well region;
a gate trench between the first drift region and the second drift region, the gate trench having a bottom defined by the well region, and two sidewalls defined by the first drift region and the second drift region, respectively, each of the two sidewalls having a step;
a gate insulating film covering the bottom and the two sidewalls of the gate trench; and
a gate electrode in the gate trench.

2. The high voltage semiconductor device of claim 1, wherein the step defines an upper sidewall and a lower sidewall of each of the two sidewalls of the gate trench, and a height of the upper sidewall is greater than a height of the lower sidewall.

3. The high voltage semiconductor device of claim 2, wherein the height of the upper sidewall is in a range of 0.2 μm to 0.5 μm, and
the height of the lower sidewall is in a range of 0.05 μm to 0.2 μm.

4. The high voltage semiconductor device of claim 2, wherein a depth from the step of the lower sidewall of each of the two sidewalls to the bottom of the gate trench is 30% or less of a total depth of the gate trench.

5. The high voltage semiconductor device of claim 2, wherein the upper sidewall and the lower sidewall are inclined.

6. The high voltage semiconductor device of claim 2, wherein the gate trench has a lower corner connecting the lower sidewall and the bottom, and an upper corner located at a lower end of the upper sidewall, and
wherein the lower corner is rounded.

7. The high voltage semiconductor device of claim 6, wherein the first drift region and the second drift region respectively cover at least a portion of the lower corner of the gate trench.

8. The high voltage semiconductor device of claim 6, wherein the upper corner is rounded.

9. The high voltage semiconductor device of claim 1, wherein a bottom of the gate electrode is at a level equal to or higher than lower surfaces of the first drift region and the second drift region.

10. The high voltage semiconductor device of claim 1, wherein the well region has a channel region defined at least partially by the bottom of the gate trench, and
an impurity concentration of the channel region is higher than an impurity concentration of the well region.

11. The high voltage semiconductor device of claim 1, wherein in a planar view, the gate electrode extends in a first direction between the first drift region and the second drift region, and an upper surface of the gate electrode defines a valley extending in the first direction.

12. The high voltage semiconductor device of claim 1, wherein the gate electrode includes extended portions on the first drift region and the second drift region adjacent to the gate trench.

13. The high voltage semiconductor device of claim 12, wherein each of the extended portions of the gate electrode has a width of 0.2 μm or less.

14. The high voltage semiconductor device of claim 12, wherein
the first drift region includes a first source/drain region and the second drift region includes a second source/drain region,
an impurity concentration of the first source/drain region is higher than an impurity concentration of the first drift region,
an impurity concentration of the second source/drain region is higher than an impurity concentration of the second drift region, and
the first source/drain region and the second source/drain region are spaced apart from the gate electrode.

15. A high voltage semiconductor device comprising:
a substrate;
a well region of a first conductivity-type in the substrate;
a first drift region and a second drift region of a second conductivity-type in the well region;
a gate trench between the first drift region and the second drift region, the gate trench having a bottom defined by the well region and two inclined sidewalls respectively defined by the first drift region and the second drift region, the bottom of the gate trench having a corner structure formed of two steps;
a gate insulating film covering the bottom and the two inclined sidewalls of the gate trench;
a gate electrode in the gate trench;
an interlayer insulating layer on the substrate and covering the first drift region and the second drift region and the gate electrode; and
a first contact plug and a second contact plug penetrating the interlayer insulating layer and respectively connected to the first drift region and the second drift region.

16. The high voltage semiconductor device of claim 15, wherein the corner structure of the two steps of the gate trench includes a lower corner adjacent to the bottom and an upper corner on the lower corner, and
the first drift region and the second drift region cover at least a portion of the lower corner.

17. The high voltage semiconductor device of claim 16, wherein the lower corner is rounded.

18. The high voltage semiconductor device of claim 15, wherein a channel region is defined in the well region at least partially by the bottom of the gate trench, and
the channel region has an impurity concentration higher than an impurity concentration of the well region.

19. A high voltage semiconductor device comprising:
a substrate;
a well region of a first conductivity-type in the substrate;
a first drift region and a second drift region of a second conductivity-type in the well region;
a gate trench between the first drift region and the second drift region and having a bottom defined at least partially by the well region and two sidewalls respectively defined by the first drift region and the second drift region, each sidewall of the two sidewalls having a step, and an upper sidewall and a lower sidewall separated by the step;
a gate insulating film covering the bottom and the two sidewalls of the gate trench;
a gate electrode in the gate trench and on the first drift region and the second drift region adjacent to the gate trench;
an interlayer insulating layer on the substrate and covering the first drift region and the second drift region and the gate electrode; and
a first contact plug and a second contact plug each penetrating the interlayer insulating layer and connected to the first drift region and the second drift region, respectively.

20. The high voltage semiconductor device of claim 19, wherein a lower corner is rounded where the lower sidewall and the bottom are connected, and the first drift region and the second drift region respectively cover at least a portion of the lower corner of the gate trench.
